(19) United States
(12) Patent Application Publication
(10) Pub. No.: US 2021/0123131 A1
(43) Pub. Date: Apr. 29, 2021

(54) METHOD FOR MANUFACTURING A DOPED METAL OXIDE FILM

(71) Applicant: Institute of Nuclear Energy Research, Atomic Energy Council, Executive Yuan, R.O.C, Taoyuan (TW)

(72) Inventors: TING-KUEI TSAI, Taoyuan (TW); YU-LIN YEH, Taoyuan (TW); MIN-CHUAN WANG, Taoyuan (TW)

(21) Appl. No.: 16/724,469

(22) Filed: Dec. 23, 2019

(30) Foreign Application Priority Data
Oct. 29, 2019 (TW) 108139041

(51) Int. Cl. C23C 14/32; H01M 4/04; C23C 14/08; H01M 4/48; G02F 1/155; G02F 1/1343

(52) U.S. Cl. CPC C23C 14/325; H01M 4/0423; C23C 14/08; G02F 1/13439; H01M 4/48; G02F 1/155; H01M 4/0404

(57) ABSTRACT

A method for manufacturing a doped metal oxide film includes following steps. First, a substrate is provided. Second, a metal oxide film is formed on the substrate by using a capacitive pulsed arc plasma technique to control a metal ion film to be doped, and by integrating an arc plasma coating process or a physical vapor deposition process. The invention completes the in-situ doping function of metal oxides and compounds in a single process, and can be used for manufacturing functional components for continuous processes without breaking vacuum condition, and is applied to the thin film process of electrochemical components such as electrochromic devices or lithium batteries.

### CROSS REFERENCE TO RELATED APPLICATION

This application claims the benefits of Taiwan application Serial No. 108139041, filed on Oct. 29, 2019, the disclosures of which are incorporated by references herein in its entirety.

### TECHNICAL FIELD

The present invention relates to an ion film doping technology, and more particularly to a method for manufacturing a doped metal oxide film.

### BACKGROUND

In recent years, the global greenhouse effect has been severe. How to make good use of the thin film process to achieve energy storage and energy conservation is one of the major energy policies of all countries in the world. In modern architecture, glass has been widely used. When it is widely used in buildings and vehicles, it will produce high temperatures. How to avoid this disadvantage is one of the key points of energy conservation. At present, in various insulation and energy-saving devices, the Smart Window can actively adjust the transmittance of visible light and heat radiation according to the user's needs in lighting and temperature. Therefore, the Smart Window has great market potential in the future development of energy-efficient buildings. According to the statistics of the international research company nanomarket in 2013, the global smart window market will have a scale of 5.6 billion US dollars by 2020. Among them, electrochromism is a low-energy electrochemical device, so it is suitable for energy-efficient buildings. In addition, electrochromic devices have many new applications in the future, such as energy-saving electronic tags and camera apertures for thin and light smart devices.

Moreover, the energy storage battery is another electrochemical component, and the secondary battery is required for daily life from smart phones, cameras, and the like, to everyday machines to automobiles and industrial equipment. According to a report released by the IDTechEx, the thin-film battery will grow to a market size of $471 million by 2026. Among them, Internet of Things (IOT), wearable devices and environmental sensors all require new design concepts that traditional battery technology cannot provide. According to a research conducted by another market research firm, WinterGreen Research, in 2015, with the improvement of technology and the reduction of manufacturing costs, the output value of solid-state thin film batteries will reach a market scale of 9 million US dollars in 2014, and rapidly grow to 1.3 billion in 2021. Therefore, the field of applying new secondary batteries will continue to increase, and the market scale will continue to expand. In addition, the use of a new generation of secondary batteries involves small consumer electronic products such as mobile phones, computers, and IC cards, as well as large-scale industrial equipment such as electric vehicles for transportation vehicles, residential power storage systems, and smart grids. At present, domestic and foreign manufacturers mainly focus on the development of lithium-ion batteries, and the patents have been completed, and there are not many breakthroughs. For all-solid-state thin-film batteries, the cost cannot be reduced to an ideal value due to the high threshold coating technology and the low film coating rate.

Today's common electrochemical device products mainly use metal oxides, which often encounters bottlenecks in the coating process that the magnetically controlled plasma coating rate is too low to be mass-produced. Besides, it is usually necessary to dope the functional metal ions in the metal oxide film to make electrochemical devices. The functional metal ion function achieved by external impregnation in the process is usually accompanied by an increase in process cost and instability in device fabrication. On the other hand, the direct mix of low-melting metal during the production of the target is more likely to cause instability of the target itself and increase the difficulty of manufacturing the target, and is also susceptible to the low coating rate in the coating process.

Since the above-mentioned electrochemical devices are required to be fabricated in a series of magnetron sputtering films, the production cost is relatively high, so that it is still not popular today. In order to solve the above problems, it is necessary to complete the in-situ doping function of metal oxides and compounds in a single process, and apply to the thin film process of existing electrochemical components such as electrochromic or lithium batteries, thereby effectively reducing the production cost and improving performance of electrochemical devices.

### SUMMARY

An objective of the present invention is to provide a method for manufacturing a doped metal oxide film. The method uses a doping technique for a tunable metal in a capacitive pulsed arc plasma, such as a Lithium Li, indium In, bismuth Bi, magnesium Mg, aluminum Al, nickel Ni, titanium Ti, chromium Cr, molybdenum Mo, tantalum Ta, iron Fe, tungsten W, zirconium Zr, niobium Nb, manganese Mn, cobalt Co, copper Cu, silver Ag, gold Au, zinc Zn, tin Sn or carbon C ion film.

The present invention achieves the above-indicated objective by providing a method for manufacturing a doped metal oxide film. The method includes following steps. First, a substrate is provided. Second, a metal oxide film is formed on the substrate by using a capacitive pulsed arc plasma technique to control a metal ion film to be doped, and by integrating an arc plasma coating process or a physical vapor deposition process.

The present invention achieves the above-indicated objective further providing a method for manufacturing an electrochemical device. The method includes following steps. First, a conductive substrate is provided. Second, an anode film of the electrochemical device of a doped metal oxide is formed on the conductive substrate by using an arc plasma coating process integrated capacitive pulsed arc plasma technique. Next, an ion conduction layer of the electrochemical device of the doped metal oxide is formed on the anode film by using the arc plasma coating process integrated capacitive pulsed arc plasma technique. Next, a cathode film of the electrochemical device of the doped metal oxide is formed on the ion conduction layer by using the arc plasma coating process integrated capacitive pulsed arc plasma technique. Finally, a conductive electrode of the electrochemical device of the doped metal oxide on the cathode film by using the arc plasma coating process integrated capacitive pulsed arc plasma technique, or by using an electroplating process or a coating process.

Compared to a conventional method for manufacturing a metal oxide film, the present invention has several advantages.

1. A capacitive pulsed arc plasma technique is used to control the metal required for doping, such as a Lithium Li, indium In, bismuth Bi, magnesium Mg, aluminum Al, nickel Ni, titanium Ti, chromium Cr, molybdenum Mo, tantalum Ta, iron Fe, tungsten W, zirconium Zr, niobium Nb, manganese Mn, cobalt Co, copper Cu, silver Ag, gold Au, zinc Zn, tin Sn or carbon C ion film, to directly complete the in-situ doping requirements of metal oxides and compounds in a single process, which can effectively control the coating quality.
2. The invention can integrate existing arc plasma film process or magnetron sputtering film process to complete the in-situ doping requirements of metal oxides and compounds.
3. It can be used in batch furnaces processes and continuous coating processes to reduce the production cost of electrochemical devices.
4. At present, the doping method can only perform metal coating or impregnation on the surface of the original coating, and then use the subsequent thermal energy or electric energy for diffusion, and cannot be doped with metal elements of continuous and adjustable proportion. The capacitive pulsed arc plasma technique can effectively control the amount of metal doping in the arc or physical vapor deposition film process to achieve the composition of the metal elements in the coating layer and its specific profile.

### BRIEF DESCRIPTION OF THE DRAWINGS

FIG. 1 is a schematic view of a method for manufacturing a doped metal oxide film of the present invention

FIG. 2 is a flow chart of a method for manufacturing a doped metal oxide film of the present invention.

FIG. 3 is a schematic view of a method for manufacturing an electrochemical device of the present invention.

FIG. 4 is a flow chart of a method for manufacturing an electrochemical device of the present invention.

### DETAILED DESCRIPTION

The present invention uses a capacitive pulsed arc plasma technique to control a metal ion film to be doped, and integrates an arc plasma coating process or a physical vapor deposition process. The invention completes the in-situ doping function of metal oxides and compounds in a single process, and can be used for manufacturing functional components for continuous processes without breaking vacuum condition, and is applied to the thin film process of electrochemical devices such as electrochromic devices or lithium batteries.

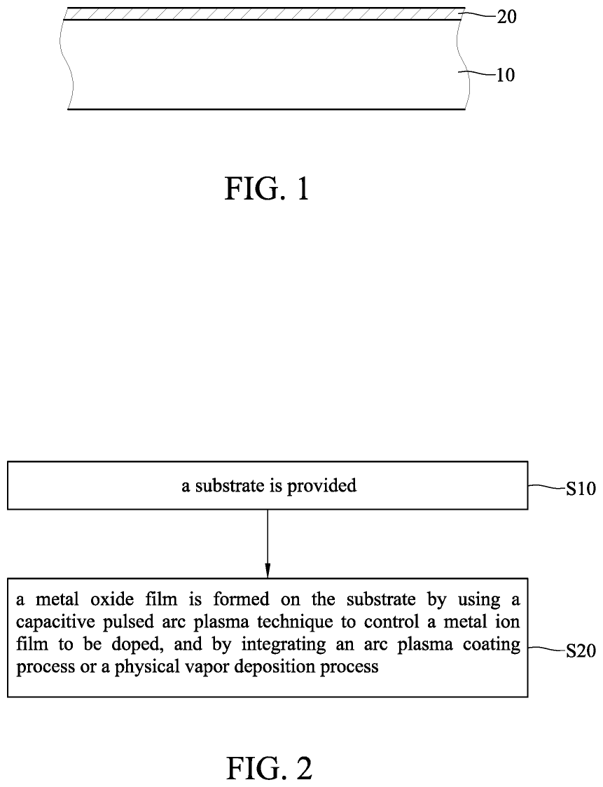

Embodiment 1: FIG. 1 is a schematic view of a method for manufacturing a doped metal oxide film of the present invention. First, as shown in FIG. 1, a substrate 10 is provided. The substrate 10 can be a metal, ceramic, semiconductor or glass substrate. Second, a metal oxide film 20 is formed on the substrate 10 by using a capacitive pulsed arc plasma technique to control a metal ion film to be doped, and by integrating an arc plasma coating process or a physical vapor deposition process.

FIG. 2 is a flow chart of a method for manufacturing a doped metal oxide film of the present invention. First, a substrate is provided, as shown in step S10. Next, a metal oxide film is formed on the substrate by using a capacitive pulsed arc plasma technique to control a metal ion film to be doped, and by integrating an arc plasma coating process or a physical vapor deposition process, as shown in step S20.

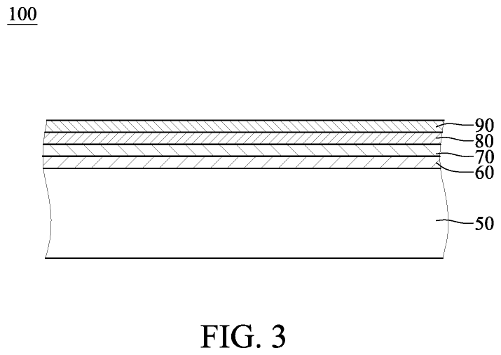

Embodiment 2: FIG. 3 is a schematic view of a method for manufacturing an electrochemical device of the present invention. The electrochemical device 100 of the present invention is a secondary battery or an electrochromic device. First, as shown in FIG. 3, a conductive substrate 50 is provided. The conductive substrate 50 can be a metal, conductive ceramic, semiconductor or conductive glass substrate. Second, an anode film 60 of the electrochemical device 100 of a doped metal oxide is formed on the conductive substrate 50 by using an arc plasma coating process integrated capacitive pulsed arc plasma technique. Next, an ion conduction layer 70 of the electrochemical device 100 of the doped metal oxide is formed on the anode film 60 by using the arc plasma coating process integrated capacitive pulsed arc plasma technique. Next, a cathode film 80 of the electrochemical device 100 of the doped metal oxide is formed on the ion conduction layer 70 by using the arc plasma coating process integrated capacitive pulsed arc plasma technique. Finally, a conductive electrode 90 of the electrochemical device 100 of the doped metal oxide on the cathode film 80 by using the arc plasma coating process integrated capacitive pulsed arc plasma technique, or by using an electroplating process or a coating process.

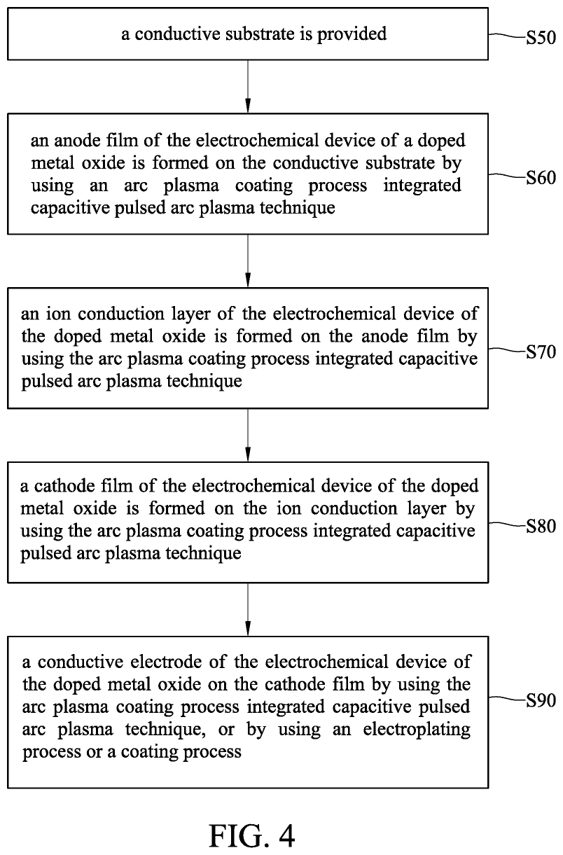

FIG. 4 is a flow chart of a method for manufacturing an electrochemical device of the present invention. First, a conductive substrate is provided, as shown in step S50. Second, an anode film of the electrochemical device of a doped metal oxide is formed on the conductive substrate by using an arc plasma coating process integrated capacitive pulsed arc plasma technique, as shown in step S60. Next, an ion conduction layer of the electrochemical device of the doped metal oxide is formed on the anode film by using the arc plasma coating process integrated capacitive pulsed arc plasma technique, as shown in step S70. Next, a cathode film of the electrochemical device of the doped metal oxide is formed on the ion conduction layer by using the arc plasma coating process integrated capacitive pulsed arc plasma technique, as shown in step S80. Finally, a conductive electrode of the electrochemical device of the doped metal oxide on the cathode film by using the arc plasma coating process integrated capacitive pulsed arc plasma technique, or by using an electroplating process or a coating process, as shown in step S90.

Parameters of the arc plasma coating process of Embodiment 1 and 2 are DC 30 to 60 A and vacuum degree 1×10⁻³ to 5×10⁻² torr. Parameters of the capacitive pulse arc plasma technique of Embodiment 1 and 2 are vacuum degree 1×10⁻³ to 5×10⁻² torr, working frequency 1 to 20 Hz and voltage 50 to 400 V. The doped metal of Embodiment 1 and 2 has a resistivity less than or equal to 0.01 ohm·cm. The doped metal is Lithium Li, indium In, bismuth Bi, magnesium Mg, aluminum Al, nickel Ni, titanium Ti, chromium Cr, molybdenum Mo, tantalum Ta, iron Fe, tungsten W, zirconium Zr, niobium Nb, manganese Mn, cobalt Co, copper Cu, silver Ag, gold Au, zinc Zn, tin Sn, carbon C or their alloy.

What is claimed is:

1. A method for manufacturing a doped metal oxide film, comprising the steps of:
providing a substrate; and
form a metal oxide film on the substrate by using a capacitive pulsed arc plasma technique to control a metal ion film to be doped, and by integrating an arc plasma coating process or a physical vapor deposition process.

2. The method for manufacturing a doped metal oxide film as recited in claim 1, wherein parameters of the arc plasma coating process are DC 30 to 60 A and vacuum degree 1×10⁻³ to 5×10⁻² torr, and parameters of the capacitive pulse arc plasma technique are vacuum degree 1×10⁻³ to 5×10⁻² torr, working frequency 1 to 20 Hz and voltage 50 to 400 V.

3. The method for manufacturing a doped metal oxide film as recited in claim 1, wherein the doped metal has a resistivity less than or equal to 0.01 ohm·cm.

4. The method for manufacturing a doped metal oxide film as recited in claim 3, wherein the doped metal is Lithium Li, indium In, bismuth Bi, magnesium Mg, aluminum Al, nickel Ni, titanium Ti, chromium Cr, molybdenum Mo, tantalum Ta, iron Fe, tungsten W, zirconium Zr, niobium Nb, manganese Mn, cobalt Co, copper Cu, silver Ag, gold Au, zinc Zn, tin Sn, carbon C or their alloy.

5. A method for manufacturing an electrochemical device, comprising the steps of:
providing a conductive substrate; and
forming an anode film of an electrochemical device of a doped metal oxide on the conductive substrate by using an arc plasma coating process integrated capacitive pulsed arc plasma technique.

6. The method for manufacturing an electrochemical device as recited in claim 5, further comprising a step of forming an ion conduction layer of the electrochemical device of the doped metal oxide on the anode film by using the arc plasma coating process integrated capacitive pulsed arc plasma technique.

7. The method for manufacturing an electrochemical device as recited in claim 6, further comprising a step of forming a cathode film of the electrochemical device of the doped metal oxide on the ion conduction layer by using the arc plasma coating process integrated capacitive pulsed arc plasma technique.

8. The method for manufacturing an electrochemical device as recited in claim 7, further comprising a step of forming a conductive electrode of the electrochemical device of the doped metal oxide on the cathode film by using the arc plasma coating process integrated capacitive pulsed arc plasma technique, or by using an electroplating process or a coating process.

9. The method for manufacturing an electrochemical device as recited in claim 5, wherein parameters of the arc plasma coating process are DC 30 to 60 A and vacuum degree 1×10⁻³ to 5×10⁻² torr, and parameters of the capacitive pulse arc plasma technique are vacuum degree 1×10⁻³ to 5×10⁻² torr, working frequency 1 to 20 Hz and voltage 50 to 400 V.

10. The method for manufacturing an electrochemical device as recited in claim 5, wherein the doped metal has a resistivity less than or equal to 0.01 ohm·cm.

11. The method for manufacturing an electrochemical device as recited in claim 10, wherein the doped metal is Lithium Li, indium In, bismuth Bi, magnesium Mg, aluminum Al, nickel Ni, titanium Ti, chromium Cr, molybdenum Mo, tantalum Ta, iron Fe, tungsten W, zirconium Zr, niobium Nb, manganese Mn, cobalt Co, copper Cu, silver Ag, gold Au, zinc Zn, tin Sn, carbon C or their alloy.

12. The method for manufacturing an electrochemical device as recited in claim 5, wherein the electrochemical device is a secondary battery or an electrochromic device.
